(19) United States
(12) Patent Application Publication
(10) Pub. No.: US 2013/0162125 A1
(43) Pub. Date: Jun. 27, 2013

(54) SERVER CABINET

(71) Applicant: AN-GANG LIANG, Shenzhen City (CN)

(72) Inventor: AN-GANG LIANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/370,325

(22) Filed: Feb. 10, 2012

(30) Foreign Application Priority Data
Dec. 27, 2011 (CN) 201110444430.9

(51) Int. Cl. H05K 5/02

(52) U.S. Cl. 312/223.2

(57) ABSTRACT

A server cabinet includes four posts and four supporting apparatus installed to the corresponding posts. Each supporting apparatus includes a supporting member. The supporting member includes a connecting plate mounted to the corresponding post, a supporting plate extending from a first side of the connecting plate to support a server, and a positioning plate extending from a second of the connecting plate opposite to the supporting plate to engage with the server.

### BACKGROUND

1. Technical Field

The present disclosure relates to a server cabinet.

2. Description of Related Art

Generally, a plurality of servers is mounted within a server cabinet. Each server is slidably inserted into the server cabinet through sliding rails or long mounting brackets, however, such mounting structure is complex.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an exemplary embodiment of a server cabinet, together with a server.

FIG. 2 is an enlarged view of the circled portion II of FIG. 1.

FIG. 3 is an assembled, isometric view of FIG. 1.

FIG. 4 is an enlarged view of the circled portion IV of FIG. 3.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

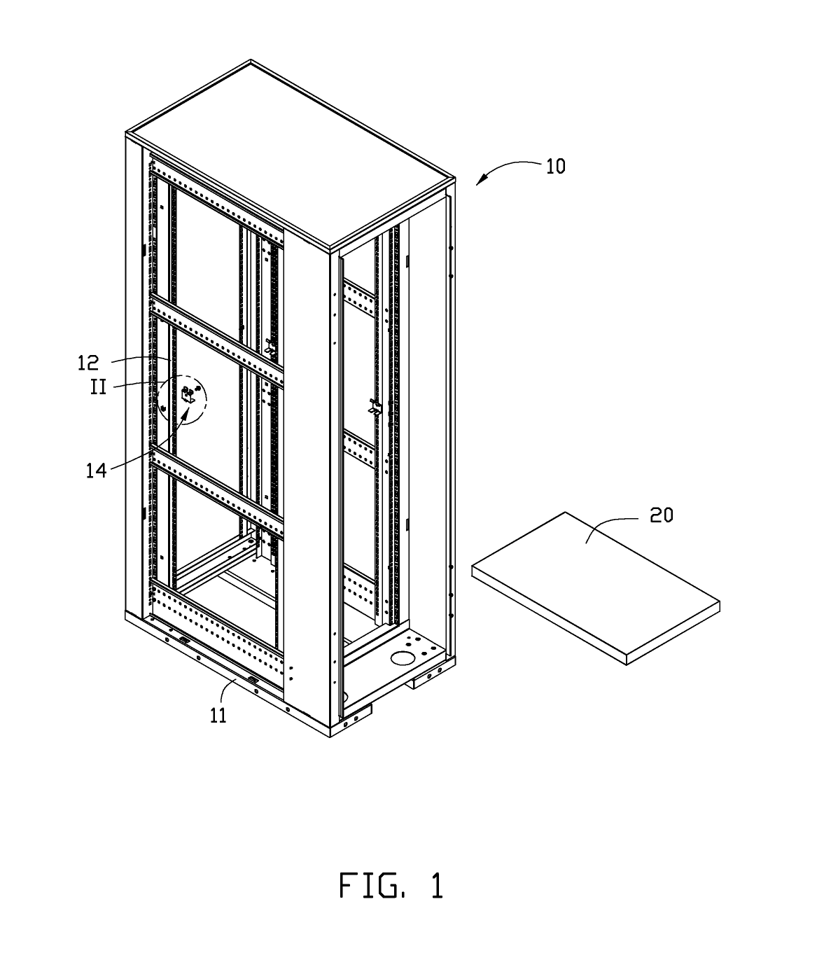

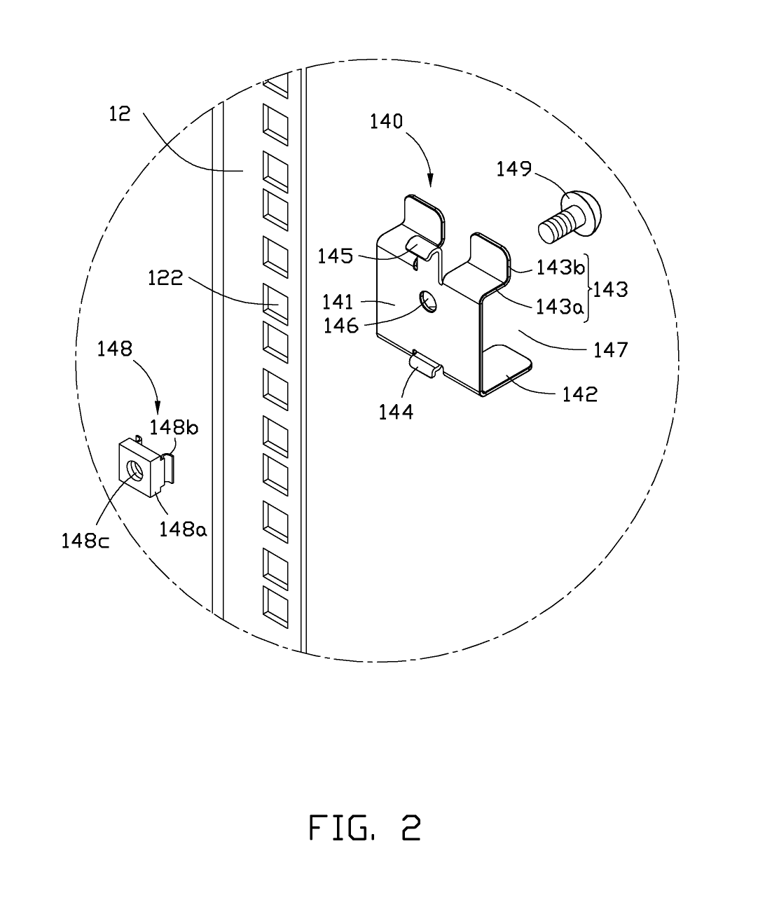

Referring to FIG. 1 and FIG. 2, an exemplary embodiment of a server cabinet for holding a server 20 includes a rack 10 and four supporting apparatus 14.

The rack 10 includes a rectangular bottom wall 11, and four posts 12 perpendicularly extending up from four corners of the bottom wall 11. A plurality of mounting holes 122 is defined in each post 12 along the lengthwise direction of the post 12.

Each supporting apparatus 14 includes a supporting member 140, a nut 148, and a screw 149.

The supporting member 140 includes a rectangular connecting plate 141, two supporting plates 142 perpendicularly extending out from two opposite ends of a first side of the connecting plate 141, and two L-shaped positioning plates 143 extending out from two opposite ends of a second side, opposite to the first side of the connecting plate 141. The positioning plates 143 are opposite to the supporting plates 142. A hook 144 extends out from the first side of the connecting plate 141 between the supporting plates 142, extending away from the supporting plates 142. A resilient L-shaped latching portion 145 extends up from the second side between the positioning plates 143, opposite to the hook 144. The connecting plate 141 defines a through hole 146 between the hook 144 and the latching portion 145. Each positioning plate 143 includes an extension portion 143a substantially perpendicularly extending from the connecting plate 141, and an engaging portion 143b substantially perpendicularly extending up from a distal end of the extending portion 143a. The supporting plates 142 and the positioning plates 143 cooperatively bound a slot 147.

The nut 148 includes a rectangular main body 148a, and two semicircular and resilient abutting portions 148b extending out from two opposite sides of the main body 148a. The main body 148a defines a screw hole 148c between the abutting portions 148b.

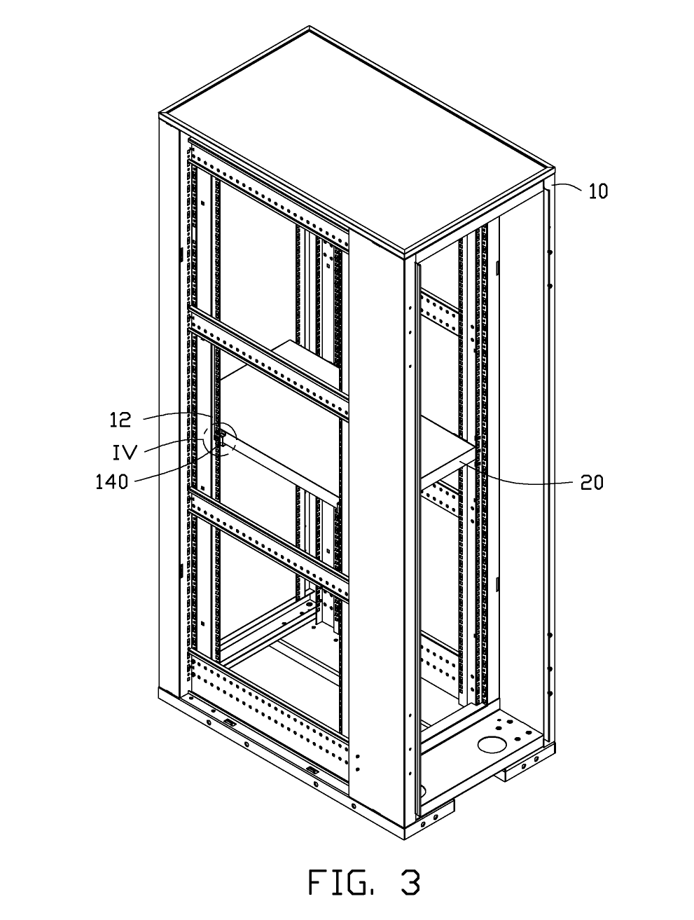

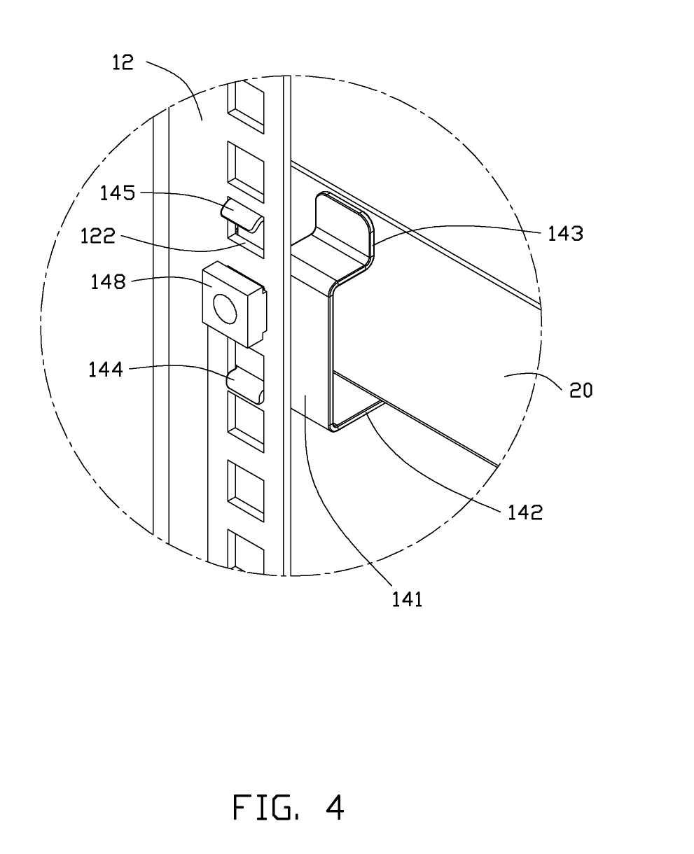

Referring to FIGS. 3-4, in assembly, the abutting portions 148b of each nut 148 are deformed toward each other to be inserted into a corresponding mounting hole 122 from the outside of rack 10. The abutting portions 148b are released then self-restored to latch to two opposite sides bounding the mounting hole 122. The screw hole 148c aligns with the mounting hole 122. The nuts 148 are installed in the corresponding posts 12 and coplanar with each other. Each supporting member 140 is located in the rack 10 opposite to the corresponding nut 148. The hook 144 is inserted into a corresponding mounting hole 122 below the nut 148. The latching portion 145 is resiliently abutted against a sidewall bounding another corresponding mounting hole 122 above the nut 148. The screw 149 extends through the through hole 146 and the corresponding mounting hole 122, to be screw into the screw hole 148c. The supporting plates 142 of the supporting members 140 are coplanar with each other.

In assembly of the server 20 to the bracket 10, an end of the server 20 is inserted into the slots 147 of the supporting members 140. The bottom of the server 20 is slidably supported on the supporting plates 142, two opposite side surfaces of the server 20 are slidably abutted against the engaging portion 143b, until the server 20 is mounted within the rack 10.

While the disclosure describes examples and embodiments, it is to be understood that the disclosure is not limited thereto. On the contrary, the disclosure is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A server cabinet, comprising:
two rows of posts, each row of posts comprising two parallel posts; and
four supporting apparatus each mounted to a corresponding one of the four posts, each supporting apparatus comprising a supporting member, wherein the supporting member comprises a connecting plate fixed to the corresponding post, a supporting plate extending out from a first side of the connecting plate for supporting a server, and a positioning plate extending out from a second side of the connecting plate opposite to the supporting plate for abutting against the server.

2. The server cabinet of claim 1, wherein each post comprises three mounting holes defined therein along a lengthwise direction of the post, each supporting apparatus further comprises a nut and a screw, the connecting plate defines a through hole, the screw extends through the through hole and a first one of the mounting holes and is screwed into the screw hole of the nut.

3. The server cabinet of claim 2, wherein a hook extends from the first side of the connecting plate, extending away from the supporting plate, the hook is latched into a second one of the mounting holes below the first mounting hole.

4. The server cabinet of claim 3, wherein a resilient latching portion extends up from the second side of the connecting plate, the latching portion is abutted against a sidewall bounding a third one of the mounting holes above the first mounting hole.

5. The server cabinet of claim 2, wherein the nut comprises a main body, and two resilient abutting portions extending out from two opposite sides of the main body, the abutting portions latch to two opposite sides bounding the first mounting hole.

6. The server cabinet of claim 2, wherein each positioning plate comprises an extension portion extending from the connecting plate, and an engaging portion extending up from a distal end of the extension portion for engaging with the server.
